(19) United States
(12) Patent Application Publication
(10) Pub. No.: US 2010/0313811 A1
(43) Pub. Date: Dec. 16, 2010

(54) EVAPORATION SOURCE AND FILM-FORMING DEVICE

(75) Inventors: Haruhiko Yamamoto, Chigasaki-shi (JP); Kenjiro Kokubu, Chigasaki-shi (JP)

Correspondence Address: J. Rodman Steele;Novak Druce & Quigg LLP, 525 Okeechobee Blvd, Suite 1500, West Palm Beach, FL, 33401, US

(73) Assignee: ULVAC Inc., Kanagawa (JP)

(21) Appl. No.: 12/918,980

(22) PCT Filed: Apr. 8, 2009
(86) PCT No.: PCT/JP2009/057227

§ 371 Date: Aug. 23, 2010

(30) Foreign Application Priority Data
Apr. 9, 2008 (JP) 2008 101605

(51) Int. Cl. C23C 16/448

(52) U.S. Cl. 118/719; 118/726

(57) ABSTRACT

A vaporization source (20) that improve the usage efficiency of a film formation material (29) without adversely affecting the maintenance characteristics. The vaporization source (20) includes a single tubular peripheral wall (25) including a plurality of storage compartments (25S) and a plurality of partitions (27) partitioning the interior of the peripheral wall (25) into the plurality of storage compartments. The peripheral wall (25) includes a plurality of holes (28), with at least one hole provided for each of the storage compartments (25S). The plurality of holes (28) communicate the plurality of storage compartments with the exterior to vaporize the film formation material (29) stored in each of the plurality of storage compartments (25S) toward the exterior.

### TECHNICAL FIELD

The present invention relates to a vaporization source and a film formation device.

### BACKGROUND ART

An optical thin film used in optical products includes a plurality of layers having different refractive indexes. Each layer is stacked onto a substrate to obtain various types of optical characteristics, such as an antireflective characteristic, a filtering characteristic, and a reflective characteristic. For example, an oxide of a metal such as tantalum, titanium, niobium, and zirconium is used as a high refractive index material. For example, a silicon oxide or magnesium fluoride is used as the low refractive index material.

The manufacturing operation for an optical thin film includes the so-called sputtering process, which uses a plurality of targets formed by dielectrics of a low refractive index material, high refractive index material, or the like and sequentially deposits sputtering grains released from the targets onto the substrate. Such type of sputtering processes includes a magnetron sputtering process, which implants plasma near the surface of the target, and a high frequency sputtering process, which applies high frequency power to the targets.

When using a dielectric as the target material for the sputtering method, the charge accumulated in the dielectric has a tendency to cause abnormal discharge. Thus, the high frequency sputtering process is generally selected. However, when using the high frequency sputtering process, in comparison to the magnetron sputtering process, the plasma density has a tendency to vary more easily when the substrate undergoes transportation and the like and the film forming speed may be greatly decreased. Various proposals have been made in the prior art for the manufacturing method of the optical thin film to solve such problems.

A film formation device described in patent document 1 arranges a rotary drum inside a vacuum chamber and forms a plurality of processing regions inside the vacuum chamber in the circumferential direction of the rotary drum. For example, a processing region for forming a metal layer using the magnetron sputtering process, a processing region for forming a silicon layer using the magnetron sputtering process, and a processing region for generating oxygen plasma and performing an oxidation process are formed around the rotary drum. The film formation device described in patent document 1 rotates the rotary drum to selectively and repetitively perform the formation of a metal layer, the formation of a silicon layer, and the oxidation of each layer on the surface of a substrate mounted on the rotary drum. Patent document 1 allows for the deposition of the high refractive index material and the deposition of the low refractive index material to be accelerated under stable deposition conditions. This increases the stability and speed of the process for forming the optical thin film.

The optical characteristics of optical thin films used in optical products easily deteriorate when various types of liquids from the exterior collect on the surface of the thin film. Thus, it is desirable that a liquid repellent film having liquid repellency for repelling various types of liquids be formed on the surface of the optical thin film. As a technique for forming the liquid repellent film, the so-called vapor deposition polymerization is used, which vapor-deposits on the surface of an optical thin film a silane coupling agent that contains a liquid repellent group for repelling liquid and a hydrolytic condensation group.

When vapor-depositing a film formation material on a substrate surface, the concentration of the film formation material is generally high near a vaporization source. Thus, to obtain a uniform film thickness, the vaporization source must be spaced by a large distance from the substrate. As a result, during formation of the liquid repellant film, the film formation material from the vaporization source is also dispersed outward from the substrate in an unnecessary manner. This drastically lowers the usage efficiency of the film formation material. Such a problem may be avoided by arranging a plurality of vaporization sources near the substrate.

However, whenever replenishing the film formation material, as the quantity of the vaporization sources increases, more time would be required for the detachment and attachment of the vaporization sources. This would adversely affect the maintenance characteristics of the film formation device.

### Prior Art Document

Patent Document 1: Japanese Laid-Open Patent Publication No. 2007-247028

### DISCLOSURE OF THE INVENTION

The present invention provides a vaporization source that improves the usage efficiency of the film formation material without affecting the maintenance characteristics and a film formation device including the vaporization source.

One aspect of the present invention is a vaporization source. The vaporization source includes a single tubular peripheral wall including a plurality of storage compartments and a plurality of partitions partitioning the interior of the peripheral wall into the plurality of storage compartments. The peripheral wall includes a plurality of holes, with at least one of the holes provided for each of the storage compartments. The plurality of holes communicate the plurality of storage compartments with the exterior to vaporize the film formation material stored in each of the plurality of storage compartments toward the exterior.

A further aspect of the present invention is a film formation device. The film formation device includes a vacuum chamber, a rotary mechanism that rotates a substrate in the vacuum chamber, and a film formation unit that vaporizes a film formation material toward the rotated substrate to form a thin film on the substrate. The film formation unit includes a vaporization source storing the film formation material and a heating unit that heats the vaporization source and vaporizes the film formation material from the vaporization source. The vaporization source includes a single peripheral wall including a plurality of storage compartments and formed to be tubular and extend in a rotational axis direction of the substrate and a plurality of partitions partitioning the interior of the peripheral wall into the plurality of storage compartments in the rotational axis direction. The peripheral wall includes a plurality of holes, with at least one of the holes provided for each of the storage compartments. The plurality of holes extend through the peripheral wall from the plurality of storage compartments toward the substrate to vaporize the film formation material stored in each of the plurality of storage compartments toward the substrate.

### BRIEF DESCRIPTION OF THE DRAWINGS

FIG. 1 is a schematic diagram showing a film formation device;

FIG. 2 is a front view showing a vaporization source;

FIG. 3 is a side view showing the vaporization source; and

FIG. 4 is a diagram showing a vaporization state of a silane coupling agent from the vaporization source.

### EMBODIMENTS OF THE INVENTION

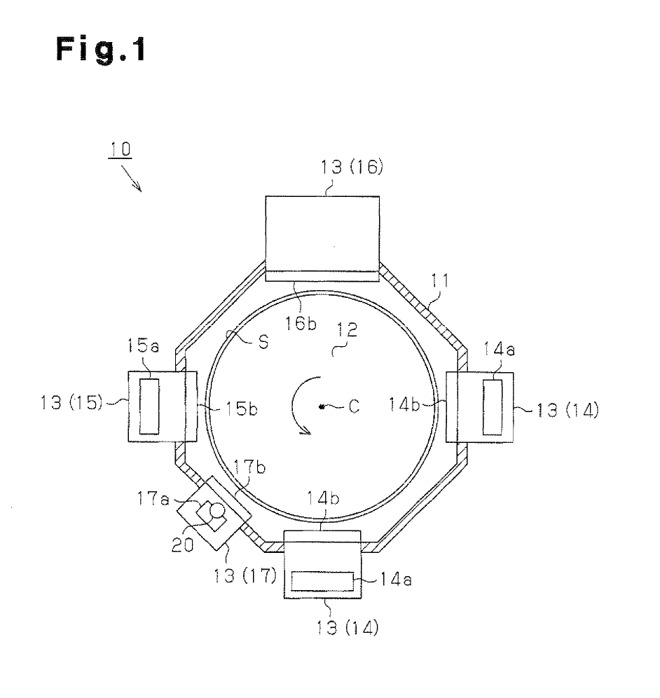

A film formation device 10 according to one embodiment will now be described with reference to the drawings. FIG. 1 is a schematic plan view showing the film formation device 10. In FIG. 1, the film formation device 10 includes a vacuum chamber 11, which has the shape of a polygonal case extending a vertical direction with respect to the plane of the drawing (hereinafter simply referred to as the rotational axis direction).

The vacuum chamber 11 includes therein a cylindrical rotary drum 12 extending in the rotational axis direction. The rotary drum 12 is one example of a rotary mechanism. The rotary drum 12 rotates about its center axis (hereinafter simply referred to as the rotation axis C) in the counterclockwise direction (direction of the arrow shown in FIG. 1) at a predetermined rotation speed such as 100 rpm. The rotary drum 12 is a holder that holds in a separable manner a substrate S serving as a film formation subject along its outer circumferential surface. The rotary drum 12 rotates the substrate S in the circumferential direction of the rotary drum 12 while keeping the surface of the substrate S facing toward the inner surface of the vacuum chamber 11.

The vacuum chamber 11 includes a plurality of surface processing units 13 arranged at the radially outward side of the rotary drum 12, that is, at positions facing toward the rotating path of the substrate S. The plurality of surface processing units 13 supply a plurality of different film formation grains or oxidation gas towards the outer circumferential surface of the rotary drum 12, that is, the surface of the substrate S. In one example, the vacuum chamber 11 includes a first film formation processing unit 14 for supplying metal grains to the substrate S, a second film formation processing unit 15 for supplying silicon grains to the substrate S, and an oxidation processing unit 16 for supplying active oxygen to the substrate S. The first film formation processing unit 14, the second film formation processing unit 15, and the oxidation processing unit 16 are examples of an oxide film formation unit. The example shown in FIG. 1 includes a plurality of (e.g., two) first film formation processing units 14. The vacuum chamber 11 also includes a third film formation processing unit 17 (film formation unit) for supplying the substrate S with a liquid material (film formation material). As the liquid material, a silane coupling agent, which contains a liquid repellent group for repelling repelling liquid and a hydrolytic polycondensation group, for example, C₈F₁₇C₂H₄Si (OCH₃)₃, may be used.

The first film formation processing unit 14 includes a first target 14a, which is formed from a metal such as tantalum and aluminum, an electrode (not shown) for sputtering the first target 14a, and a first shutter 14b for opening and closing the side closer to the rotary drum 12 when viewed from the first target 14a. When performing a film formation process, the first film formation processing unit 14 opens the first shutter 14b to supply the metal grains released from the first target 14a to the outer circumferential surface of the rotary drum 12, that is, the surface of the substrate S. When the film formation process is not performed, the first film formation processing unit 14 closes the first shutter 14b to prevent the first target 14a from being contaminated by other elements.

The second film formation processing unit 15 includes a second target 15a, which is formed from silicon, an electrode (not shown) for sputtering the second target 15a, and a second shutter 15b for opening and closing the side closer to the rotary drum 12 when viewed from the second target 15a. When performing a film formation process, the second film formation processing unit 15 opens the second shutter 15b to supply the silicon grains released from the second target 15a to the surface of the substrate S. When the film formation process is not performed, the second film formation processing unit 15 closes the second shutter 15b to prevent the second target 15a from being contaminated by other elements.

The oxidation processing unit 16, which is an oxygen plasma source for generating plasma with oxygen gas, holds an oxidation shutter 16b for opening and closing the side closer to the rotary drum 12. When performing an oxidation process, the oxidation processing unit 16 opens the oxidation shutter 16b to emit the oxygen plasma generated by the oxygen plasma source toward the surface of the substrate S. When the oxidation process is not performed, the oxidation processing unit 16 closes the oxidation shutter 16b to prevent the plasma source from being contaminated by other elements.

The third film formation processing unit 17 includes a vaporization source 20 accommodating the silane coupling agent, a heater 17a serving as a heating unit for heating the vaporization source 20, and a third shutter 17b for opening and closing the side closer to the rotary drum 12 as viewed from the vaporization source 20. The third film formation processing unit 17 drives the heater 17a and opens the third shutter 17b when forming the liquid repellent film to supply the surface of the substrate S with the silane coupling agent released from the vaporization source 20. When the liquid repellent film is not formed, the third film formation processing unit 17 closes the third shutter 17b to prevent the vaporization source 20 from being contaminated by other elements.

When forming the optical thin film on the substrate S, the film formation device 10 rotates the rotary drum 12 at a predetermined speed and drives the first film formation processing unit 14, the second film formation processing unit 15, the oxidation processing unit 16, and the third film formation processing unit 17 in a state in which the first shutter 14b, the second shutter 15b, the oxidation shutter 16b, and the third shutter 17b are closed. Then, the film formation device 10 opens the first shutter 14b while rotating the rotary drum 12 to form a metal film as an oxidized film on the surface of the substrate S and opens the oxidation shutter 16b to form a metal oxide film. Further, while continuing rotation of the rotary drum 12, the film formation device 10 opens the second shutter 15b to form a silicon film as an oxidized film on the surface of the substrate S and opens the oxidation shutter 16b to form a silicon oxide film. Then, the film formation device 10 opens the third shutter 17b to form a liquid repellent film on the surface of the substrate s.

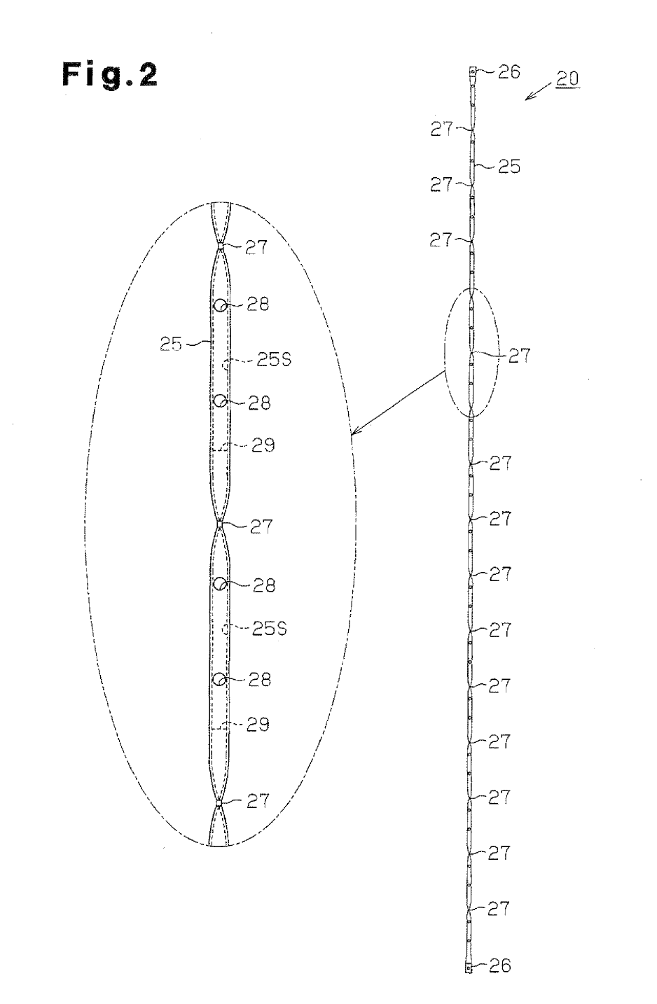

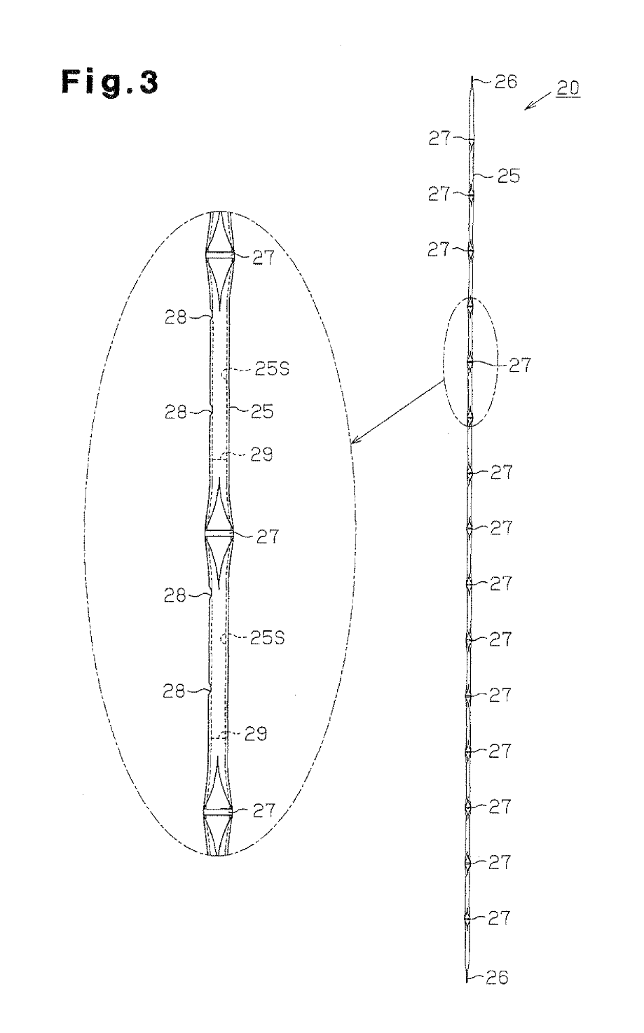

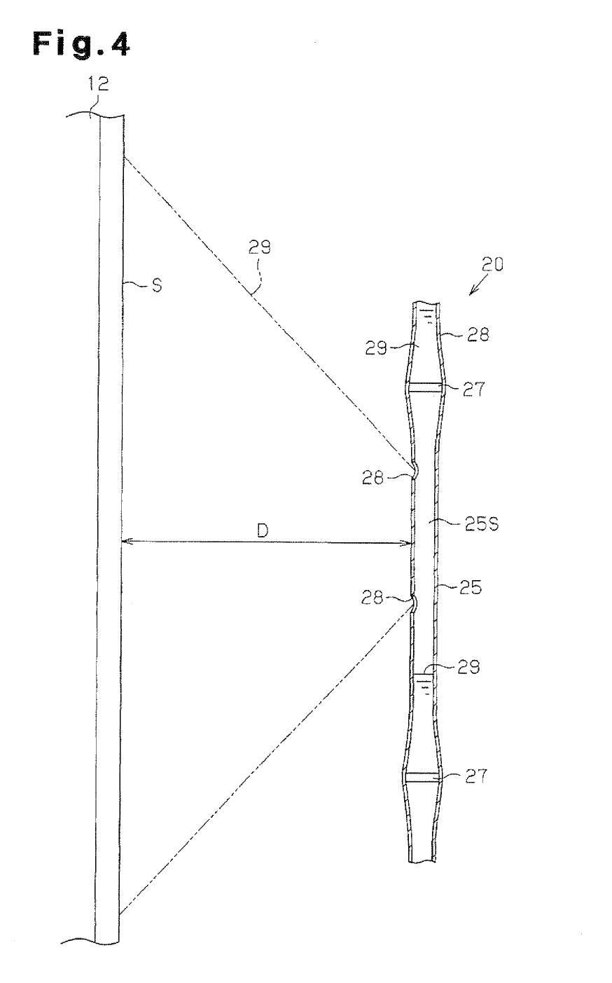

The vaporization source 20 of the third film formation processing unit 17 will now be described. FIG. 2 is a plan view showing the vaporization source 20 from the rotation axis C, and FIG. 3 is a side view showing the vaporization source 20 from the second film formation processing unit 15. FIG. 4 is a schematic diagram showing a state in which the vaporization source 20 vaporizes the silane coupling agent. Hereinafter, a direction parallel to the rotary shaft C will be referred to as the vertical direction.

Referring to FIGS. 2 and 3, the vaporization source 20 includes a tubular peripheral wall 25 extending in the vertical direction. The peripheral wall 25 has two upper and lower ends 26 that are compressed in the same direction (lateral direction as viewed in FIG. 3) to seal the interior of the peripheral wall 25 and fastened by screws to a housing of the third film formation processing unit 17. The peripheral wall 25 is formed by a tube having high thermal conductance. When receiving heat from the heater 17a, the temperature inside the peripheral wall 25 is raised to a predetermined temperature.

The peripheral wall 25 includes a plurality of partitions 27 for partitioning its interior into a plurality of storage compartments 25S in the vertical direction. The partitions 27 are each formed by compressing the peripheral wall 25 in the same direction (lateral direction as viewed in FIG. 2) to prevent gas from entering and exiting the adjacent storage compartment 25S. Each storage compartment 25S of the peripheral wall 25 includes a plurality of through holes (hereinafter simply referred to as the nozzles 28) communicating the storage compartment 25S and the vacuum chamber 11. Each nozzle 28 is formed to extend in the horizontal direction. Each nozzle 28 has an opening facing toward the outer circumferential surface of the rotary drum 12, that is, the surface of the substrate S. The plurality of storage compartments 25S each store a silane coupling agent 29, which is filled from the nozzles 28.

Referring to FIG. 4, the vaporization source 20 receives heat from the heater 17a and vaporizes the silane coupling agent 29 in each storage compartment 25S toward the surface of the substrate S. This uniformly disperses the silane coupling agent 29 in the vertical direction of the substrate S in accordance with the quantity of the storage compartments 25S. Accordingly, when obtaining the same film thickness uniformity, in relation with the dispersion of the silane coupling agent, the vaporization source 20 allows for the distance D between the substrate S and the vaporization source 20 to he shortened. As a result, the vaporization source 20 vapor-deposits most of the silane coupling agent 29, which is stored in the storage compartments 25D, on the surface of the substrate S. This improves the usage efficiency of the silane coupling agent. The single vaporization source 20 includes the plurality of storage compartments 25S. Thus, in the housing of the third film formation processing unit 17, maintenance may be performed on the vaporization source 20 entirely in the vertical direction just by detaching and attaching the two upper and lower ends 26.

By supplying a polycondensation initiator such as water, the silane coupling agent vapor-deposited on the substrate S initiates hydrolysis and a polycondensation reaction and forms a liquid repellant film on the substrate S.

The film formation device 10 of the embodiment discussed above has the advantages described below.

(1) The vaporization source 20 includes the single peripheral wall 25, which is tubular and extends in the vertical direction. The peripheral wall 25 includes the plurality of partitions 27, which partition its interior into a plurality of storage compartments 25S in the vertical direction, and the nozzles 28, which are formed in the peripheral wall 25 for each of the storage compartments 25S and communicate each of the storage compartments 25S with the interior of the vacuum chamber 11 the horizontal direction.

Accordingly, the vaporization source 20 disperses the silane coupling agent 29 in the vertical direction accordance with the quantity of the storage compartments 253. Thus, to obtain the same film thickness uniformity, the distance D between the substrate S and the vaporization source 20 may be shortened. As a result, the vaporization source 20 improves the usage efficiency of the silane coupling agent 29. Further, the single vaporization source 20 includes the plurality of storage compartments 25S. Thus, the film formation device 10 allows for maintenance to be performed entirely in the vertical direction just by detaching and attaching the single vaporization source 20. Hence, the film formation device 10 improves the usage efficiency of the silane coupling agent 29 without adversely affecting the maintenance characteristics.

(2) The plurality of partitions 27 are each formed by inwardly compressing part of the peripheral wall 25. Accordingly, each storage compartment 25S is surrounded by the partitions 27, which are continuous with the peripheral wall 25. Thus, in comparison with when attaching a discrete partition 27, the seal between the adjacent storage compartments 25S is improved. As a result, the vaporization source 20 prevents, in a preferable manner, the silane coupling agent 29 from entering and exiting the adjacent storage compartments 25S. Thus, the vaporization source 20 disperses the silane coupling agent 29 stored in the storage compartments 25S toward the opposing region of the substrate S and improves the usage efficiency of the silane coupling agent 29 in comparison to when the partitions 27 are discretely provided.

(3) Further, the plurality of partitions 27 are each formed by part of the peripheral wall 25. Thus, when manufacturing the vaporization source 20, the quantity of components is drastically reduced compared to when attaching discrete partitions. Accordingly, the productivity of the vaporization. source 20 is drastically improved.

(4) Moreover, the plurality of partitions 27 are each formed by compressing the peripheral wall 25. Thus, the vaporization source 20 is easily applicable to changes in the size of the substrate S and the film thickness uniformity. This drastically improves the degree of freedom for designing the storage compartment 25S and widens the application range for the vaporization source 20.

The embodiment discussed above may be modified as described below.

Each of the partitions 27 do not have to be formed from part of the peripheral wall 25. The partitions 27 may be formed by members that differ from the peripheral wall 25, and such discrete partitions may be attached to the peripheral wall 25. That is, the “partitions” of the vaporization source are only required to partition the interior of the peripheral wall 25 into the plurality of storage compartments 25S in the vertical direction.

The peripheral wall 25 has the shape of a circular tube but is not limited in such a manner. The peripheral wall 25 may be formed to have the shape of an elliptic tube or may be formed to be tubular and have a tetragonal cross-section. That is, the “partitions” of the vaporization source is only required to have a structure that partitions the interior of the peripheral wall 25 in the vertical direction into the plurality of storage compartments 25S.

The peripheral wall 25 has two nozzles 28 for each storage compartment 25S but is not limited to such a structure. The peripheral wall 25 may have a structure in which each storage compartment 25S has one nozzle 28 or three or more nozzles 28.

The rotary drum 12 is cylindrical but is not limited in such a manner, and the rotary drum 12 may have a polygonal shape.

1. A vaporization source for vaporizing a film formation material when receiving heat, the vaporization source comprising:
a single tubular peripheral wall including a plurality of storage compartments; and
a plurality of partitions partitioning the interior of the peripheral wall into the plurality of storage compartments;
wherein the peripheral wall includes a plurality of holes, with at least one of the holes provided for each of the storage compartments, in which the plurality of holes communicate the plurality of storage compartments with the exterior to vaporize the film formation material stored in each of the plurality of storage compartments toward the exterior.

2. The vaporization source according to claim 1, wherein each of the plurality of partitions is part of the peripheral wall in which the peripheral wall is inwardly compressed.

3. A film formation device comprising:
a vacuum chamber;
a rotary mechanism that rotates a substrate in the vacuum chamber; and
a film formation unit that vaporizes a film formation material toward the rotated substrate to form a thin film on the substrate, the film formation unit including:
a vaporization source storing the film formation material; and
a heating unit that heats the vaporization source and vaporizes the film formation material from the vaporization source, the vaporization source including:
a single peripheral wall including a plurality of storage compartments and formed to be tubular and extend in a rotational axis direction of the substrate; and
a plurality of partitions partitioning the interior of the peripheral wall into the plurality of storage compartments in the rotational axis direction;
wherein the peripheral wall includes a plurality of holes, with at least one of the holes provided for each of the storage compartments, in which the plurality of holes extend through the peripheral wall from the plurality of storage compartments toward the substrate to vaporize the film formation material stored in each of the plurality of storage compartments toward the substrate.

4. The film formation device according to claim 3, wherein each of the plurality of partitions is part of the peripheral wall in which the peripheral wall is inwardly compressed.

5. The film formation device according to claim 3, further comprising:
an oxide film formation unit that forms an oxidized film on the substrate by releasing grains toward the rotated substrate and forms an oxide film on the substrate by emitting oxygen plasma toward the oxidized film on the rotated substrate;
wherein the film formation material is a silane coupling agent containing a liquid repellent group; and
the vaporization source vaporizes the silane coupling agent toward the oxide film to form a liquid repellant film on the oxide film.

6. The film formation device according to claim 4, further comprising:
an oxide film formation unit that forms an oxidized film on the substrate by releasing grains toward the rotated substrate and forms an oxide film on the substrate by emitting oxygen plasma toward the oxidized film on the rotated substrate;
wherein the film formation material is a silane coupling agent containing a liquid repellent group; and
the vaporization source vaporizes the silane coupling agent toward the oxide film to form a liquid repellant film on the oxide film.
